(19) United States
(12) Patent Application Publication
(10) Pub. No.: US 2026/0296783 A1
(43) Pub. Date: Oct. 1, 2026

(54) STORAGE SYSTEM

(71) Applicant: Murata Machinery, Ltd., Kyoto-shi, Kyoto (JP)

(72) Inventor: Yasuhisa ITO, Kyoto-shi (JP)

(21) Appl. No.: 19/490,148

(22) PCT Filed: May 24, 2024
(86) PCT No.: PCT/JP2024/019148

§ 371 Date: Dec. 4, 2025

(30) Foreign Application Priority Data
Jun. 13, 2023 (JP) 2023-097060

(51) Int. Cl. B65G 1/04; H10P 72/30

(52) U.S. Cl. CPC B65G 1/0464; B65G 1/0457; H10P 72/3214; H10P 72/3216; H10P 72/3221; H10P 72/3404

(57) ABSTRACT

A storage system includes an automated guided vehicle to travel on a ceiling track and convey an article, and storage equipment located below and to one side of the ceiling track to receive and store an article from the automated guided vehicle. The automated guided vehicle includes a slide mechanism to laterally move a mounted article. The storage equipment includes storage sections of stages arranged in an up-down direction. The storage section of an uppermost stage includes a fixed shelf incapable of laterally advancing or retreating. The other storage sections include movable shelves to advance or retreat between a position where the storage sections advance to directly below the ceiling track and a position laterally retracted from directly below the ceiling track in a top view. The storage equipment further includes purge equipment to supply a purge gas to an article on the fixed shelf of the uppermost stage.

### BACKGROUND OF THE INVENTION

### 1. Field of the Invention

The present invention relates to storage systems and, particularly, to storage systems to store articles such as a container holding a semiconductor wafer.

### 2. Description of the Related Art

Japanese Patent Laid-Open No. S62-297050 describes an example of a conventional storage system for articles that are conveyed items in a factory. The storage system is equipped with a ceiling self-driving vehicle that conveys articles and a rack that stores the articles. The rack is arranged below and to the side of a ceiling track on which the ceiling self-driving vehicle travels, and is equipped with a plurality of shelves that are lined up in an up-down direction. The shelves are designed to move (slide) to directly below the ceiling self-driving vehicle so that articles can be transferred between the rack and the ceiling self-driving vehicle.

### SUMMARY OF THE INVENTION

In the conventional storage system described above, for example, when the articles described above are containers holding semiconductor wafers, the containers are filled with an inert gas to prevent degradation of the semiconductor wafers. When the containers are stored on the rack for an extended period of time, the inert gas gradually leaks out of the containers. Therefore, it is expected that the rack will be provided with equipment to purge an inert gas into the containers even while the articles are being stored.

When the rack is arranged in a plurality of stages in the up-down direction, all of the stages of the rack are provided with a movable shelf that moves articles to directly below the ceiling self-driving vehicle. However, when the shelf is movable, a mechanism to provide piping for purging may be complicated and problematic or even difficult to design.

Example embodiments of the present invention provide storage systems each capable of supplying a purge gas such as an inert gas to an article by a simple structure.

A storage system according to an example embodiment of the present invention includes a ceiling automated guided vehicle to travel on a ceiling track and convey an article and storage equipment that is positioned below and to a side of the ceiling track to receive an article from the ceiling automated guided vehicle and stores the article, wherein the ceiling automated guided vehicle includes a lateral movement apparatus to laterally move a mounted article, the storage equipment includes storage sections of a plurality of stages arranged in an up-down direction, the storage section of an uppermost stage of the storage equipment is a fixed storage section incapable of laterally advancing or retreating, the storage sections other than the uppermost stage are movable storage sections capable of advancing or retreating between a position where the storage sections advance to directly below the ceiling track and a position laterally retracted from directly below the ceiling track in a top view, and the storage equipment further includes purge equipment to supply a purge gas to an article placed on the fixed storage section of the uppermost stage.

In an example embodiment of the present invention configured as described above, due to the storage section of the uppermost stage of the storage equipment being a fixed storage section incapable of laterally advancing or retreating, the storage sections other than the uppermost stage being movable storage sections capable of advancing or retreating between a position where the storage sections advance to directly below the ceiling track and a position laterally retracted from directly below the ceiling track in a top view, and the storage equipment further including purge equipment to supply a purge gas to an article placed on the fixed storage section of the uppermost stage, since purge gas need only be supplied to the fixed storage section of the uppermost stage by the purge equipment even when storage sections are arranged in a plurality of stages in the up-down direction, an arrangement of piping for purging and the like can be simplified and an extremely practical storage system can be achieved.

In an example embodiment of the present invention, preferably, the movable storage sections are installed on a floor and the fixed storage section is suspended from the ceiling.

In an example embodiment of the present invention configured as described above, since the movable storage sections are installed on the floor and the fixed storage section is suspended from the ceiling, the movable storage sections other than the uppermost stage can have simple structures by installing the movable storage sections on the floor.

In an example embodiment of the present invention, preferably, all of the storage sections of the plurality of stages are suspended from the ceiling.

In an example embodiment of the present invention configured as described above, since all of the storage sections of the plurality of stages are suspended from the ceiling, a space between the storage sections of the plurality of stages and the floor can be effectively utilized.

In an example embodiment of the present invention, preferably, the fixed storage section includes a fixed shelf and the movable storage sections include movable shelves.

In an example embodiment of the present invention configured as described above, since the fixed storage section includes a fixed shelf and the movable storage sections include movable shelves, both storage sections can have simple structures.

An example embodiment of the present invention preferably further includes a controller configured or programmed to designate a storage section to store an article and instruct the ceiling automated guided vehicle to transfer the article to the designated storage section, wherein the controller is configured or programmed to instruct the ceiling automated guided vehicle to transfer the article to the fixed storage section of the uppermost stage when it is determined that the purge gas needs to be supplied to the article, and the controller is configured or programmed to instruct the ceiling automated guided vehicle to transfer the article to a movable storage section other than the uppermost stage when it is determined that the purge gas does not need to be supplied to the article.

A storage system according to an example embodiment of the present invention includes a ceiling automated guided vehicle to travel on a ceiling track and convey an article, and storage equipment that is positioned below and to a side of the ceiling track to receive an article from the ceiling automated guided vehicle and store the article, wherein the storage equipment includes a plurality of first storage sections that are arranged in an up-down direction and a second storage section that is fixed and arranged below the plurality of storage sections and directly below the ceiling track, the first storage sections of the storage equipment are movable storage sections that are capable of advancing or retreating between a position where the storage sections advance to directly below the ceiling track and a position laterally retracted from directly below the ceiling track in a top view, and the storage equipment further includes purge equipment to supply a purge gas to an article placed on the second storage section.

According to the storage systems of example embodiments of the present invention, a purge gas such as an inert gas can be supplied to an article by a simple structure.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view showing a conveyance system to which a storage system according to a first example embodiment of the present invention is applied.

FIG. 2 is a perspective view showing the storage system according to the first example embodiment of the present invention.

FIG. 3 is a front view showing a automated guided vehicle and a part of storage sections (fixed shelf) of the storage system according to the first example embodiment of the present invention.

FIG. 4 is a front view showing a part of the storage sections including purge equipment provided in the storage system according to the first example embodiment of the present invention.

FIG. 5 is a schematic view showing a system configuration of the storage system according to the first example embodiment of the present invention.

FIG. 6 is a flow chart showing operations to be executed by the storage system according to the first example embodiment of the present invention.

FIG. 7 is a perspective view showing a storage system according to a second example embodiment of the present invention.

FIG. 8 is a perspective view showing a storage system according to a third example embodiment of the present invention.

### DETAILED DESCRIPTION OF THE EXAMPLE EMBODIMENTS

Hereinafter, storage systems according to example embodiments of the present invention will be described with reference to the drawings.

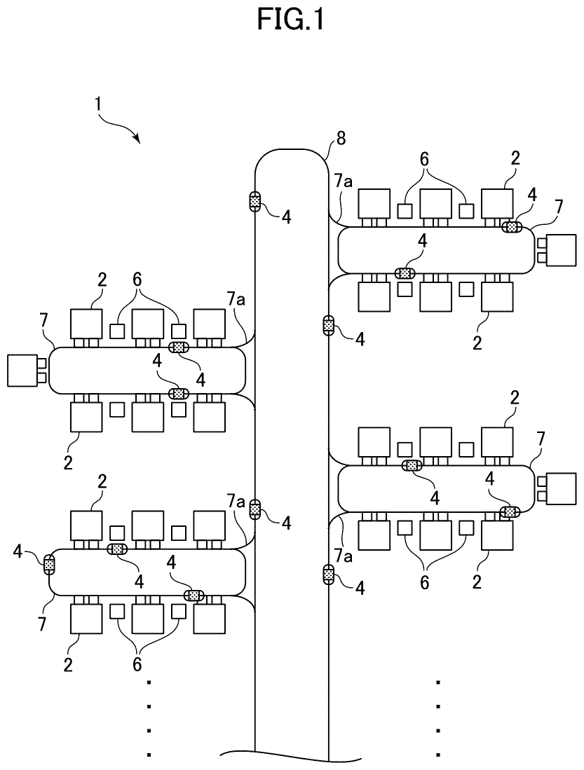

First, a basic structure of a storage system according to a first example embodiment of the present invention will be described with reference to FIGS. 1 to 3.

Note that in the present example embodiment, the present invention is applied to a storage system to store an article such as a FOUP holding a semiconductor wafer, a reticle pod housing a reticle, or the like in a clean room of a semiconductor manufacturing factory.

First, a conveyance system to which the storage system according to the first example embodiment of the present invention is applied will be described according to FIG. 1. FIG. 1 is a schematic plan view showing a conveyance system to which the storage system according to the first example embodiment of the present invention is applied.

As shown in FIG. 1, a conveyance system 1 to which the first example embodiment of the present invention is applied includes a automated guided vehicle (AGV) 4 to convey an article to be processed by a processing apparatus 2, a plurality of buffers 6 that are temporary storage sections that temporarily store an article to be conveyed, a plurality of intra-bay tracks 7 that can convey an article to the processing apparatus 2, and an inter-bay track 8 that connects the intra-bay tracks 7. Furthermore, the conveyance system 1 includes a controller (not illustrated) configured or programmed to control the automated guided vehicle 4 and convey an article processed by a first processing apparatus 2 to the buffer 6, and once a second processing apparatus 2 to perform processing of a next step with respect to the article is determined after the article is stored in the buffers 6, the controller is configured or programmed to convey the article to the second processing apparatus 2.

First, the intra-bay track 7 is a traveling track including a rail provided on a ceiling, and a plurality of the processing apparatuses 2 are arranged along the intra-bay track 7 so that articles can be conveyed to the processing apparatuses 2. By traveling in a state of being suspended from the intra-bay track 7, the automated guided vehicle 4 can convey an article M from a given processing apparatus 2 to another processing apparatus 2 that are arranged along the intra-bay track 7. In this manner, the automated guided vehicle 4 is a ceiling automated guided vehicle to travel along the traveling track provided on the ceiling. In addition, the conveyance system 1 includes a plurality of intra-bay tracks 7 and the rail of each intra-bay track 7 is suspended from the ceiling of a semiconductor manufacturing factory.

Next, the inter-bay track 8 is a traveling track including an annular rail suspended from the ceiling of the semiconductor manufacturing factory and is connected to each intra-bay track 7 via a branch track 7a, respectively. Accordingly, the automated guided vehicle 4 included in the conveyance system 1 can interchangeably enter one intra-bay track 6 from another intra-bay track 7 via the inter-bay track 8. In other words, the conveyance system 1 can convey the article M from a processing apparatus 12 arranged along a given intra-bay track 7 to another processing apparatus 12 arranged along another intra-bay track 7.

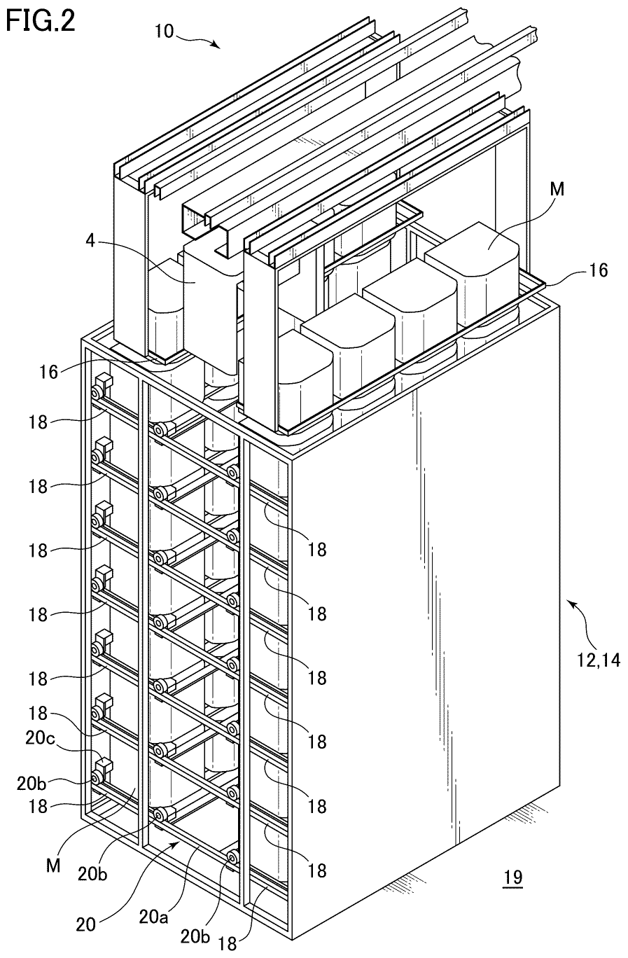

Next, the storage system according to the first example embodiment of the present invention will be described with reference to FIG. 2. FIG. 2 is a perspective view showing the storage system according to the first example embodiment of the present invention.

As shown in FIG. 2, a storage system 10 according to the first example embodiment of the present invention includes the automated guided vehicle 4 that is the ceiling automated guided vehicle described above and storage equipment 12 to store the article M.

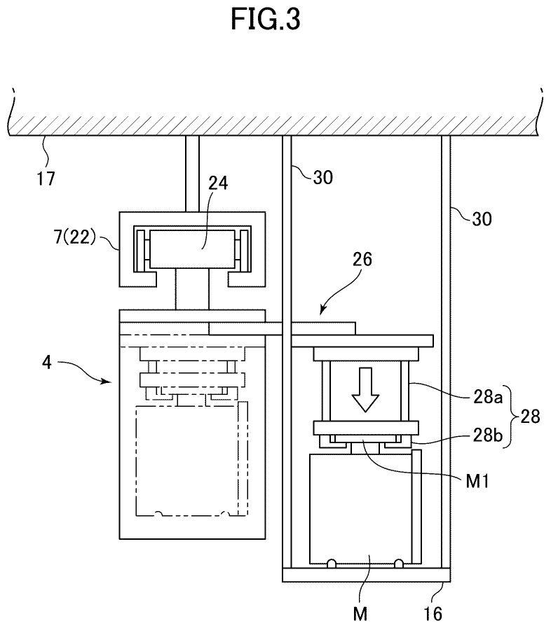

The storage equipment 12 includes multistage buffers 14 arranged on both sides (right side and left side in FIG. 2), respectively, with respect to a traveling direction of the automated guided vehicle 4. The multistage buffer 14 on one side (left side) includes a fixed shelf 16 that is a storage section on an uppermost stage and includes movable shelves 18 of seven stages in an up-down direction below the fixed shelf 16, for example. The fixed shelf 16 is suspended from a ceiling 17 (refer to FIG. 3) and is incapable of moving in a lateral direction (width direction) by itself. In addition, the movable shelves 18 are arranged on a floor 19 and are capable of moving the article M in the lateral direction (width direction) to directly below the automated guided vehicle 4.

The movable shelves 18 are configured to receive the article M from the automated guided vehicle 4 and store the article M as well as handing the stored article M to the automated guided vehicle 4 and, to that end, the movable shelves 18 can be moved in the lateral direction. Therefore, the movable shelf 18 of each stage is provided with a movement mechanism 20 to move the movable shelf 18 in the lateral direction.

The movement mechanism 20 includes a rail 20a provided below each movable shelf 18 and extending in the lateral direction, a roller 20b attached to the movable shelf 18 and travels on the rail 20a, and a drive motor 20c that rotationally drives the roller 20b. Due to the movement mechanism 20, moving the movable shelves 18 to directly below the automated guided vehicle 4 enables the article M to change hands between the movable shelves 18 and the automated guided vehicle 4.

The multistage buffer 14 on the other side (right side) is similar to the left side and includes the fixed shelf 16 that is a storage section on an uppermost stage and includes the movable shelves 18 of seven stages in an up-down direction below the fixed shelf 16. The movable shelves 18 are also provided with movement mechanisms 20 to move the movable shelves 18 in the lateral direction, and the movement mechanisms 20 also include the rail 20a, the roller 20b, and the drive motor 20c.

Next, the automated guided vehicle 4 and the fixed shelf 16 will be described with reference to FIG. 3. FIG. 3 is a front view showing the automated guided vehicle and a portion of the storage sections (fixed shelf) of the storage system according to the first example embodiment.

As shown in FIG. 3, the automated guided vehicle 4 is capable of traveling due to a traveling mechanism 24 and moving to a target position in a state of being suspended from a rail 22 of the intra-bay track 7. In addition, the automated guided vehicle 4 includes a slide mechanism 26 and a gripping mechanism 28.

The slide mechanism 26 can be extended and retracted in a horizontal direction by a ball screw drive mechanism (not illustrated), and the gripping mechanism 28 to grip a flange M1 provided in an upper part of the article M is attached to a tip. In addition, the gripping mechanism 28 includes a suspension belt 28a and a gripper 28b.

Four suspension belts 28a are provided for each automated guided vehicle 4 and are wound around a reel (not illustrated) provided at a tip of the slide mechanism 26. Furthermore, the gripper 28b includes an open/close mechanism capable of sandwiching the flange M1 of the article M.

The gripper 28b is suspended by the four suspension belts 28a and the gripper 28b moves up and down via the suspension belts 28a due to forward and backward rotations of the reel by a drive apparatus (not illustrated) such as a motor. In addition, a length of the suspension belts 28a is set so as to enable the article M on the fixed shelf 16 to be gripped by the gripper 28b and moved up and down. When the slide mechanism 26 is extended and the gripping mechanism 28 moves to a position directly above the article M, the gripper 28b is lowered to above the article M. Furthermore, the gripper 28b is configured to be opened and closed to sandwich the flange M1.

In addition, as shown in FIG. 3, the fixed shelf 16 is an overhead buffer (OHB) that is suspended from the ceiling 17 by a suspension rod 30.

Next, placement and carry-out of the article M to and from the multistage buffer 14 of the storage equipment 12 by the automated guided vehicle 4 will be described with reference to FIGS. 2 and 3.

A carry-out operation of the article M is as follows. First, when carrying out the article M in the fixed shelf 16, the automated guided vehicle 4, traveling on the intra-bay track 7 and stopped at a position opposing the multistage buffer 14, feeds out the slide mechanism 26 toward the fixed shelf 16 of the uppermost stage of the multistage buffer 14. Accordingly, the gripper 28b of the gripping mechanism 28 not gripping the article M is moved to directly above the article M. After moving the gripper 28b to directly above the target article M, the suspension belt 28a is extended to lower the gripper 28b to above the predetermined article M in the fixed shelf 16 and the flange M1 provided on the article M is gripped by the gripper 28b. Next, after gripping the article M, the suspension belt 28a is wound up by rotating the reel (not illustrated), the article M is elevated together with the gripper 28b, and the slide mechanism 26 is subsequently retracted.

Next, when carrying out the article M in the movable shelf 18, the movable shelf 18 is moved inward in the lateral direction by the movement mechanism 20 and the article M in the movable shelf 18 is moved to directly below the automated guided vehicle 4. Next, the suspension belt 28a of the gripping mechanism 28 not gripping the article M is extended without operating the slide mechanism 26 of the automated guided vehicle 4 to lower the gripper 28b to above the predetermined article M and the flange M1 provided on the article M is gripped by the gripper 28b. Next, after gripping the article M, the suspension belt 28a is wound up by rotating the reel (not illustrated) and the article M is elevated together with the gripper 28b to the automated guided vehicle 4. Subsequently, the movable shelf 18 is returned from the position directly below the automated guided vehicle 4 to its original lateral position by the movement mechanism 20.

In this manner, the automated guided vehicle 4 on, which the article M is mounted, travels on the intra-bay track 7 and the inter-bay track 8 toward a next conveyance destination of the article M.

Next, a placement operation of the article M is as follows. First, when placing the article M on the fixed shelf 16, the placement operation is similarly implemented in a reverse order of the carry-out operation. Specifically, the automated guided vehicle 4, traveling on the intra-bay track 7 while gripping the article M with the gripper 28b, stops at a predetermined position opposing the fixed shelf 16 on which the article M is to be placed. Next, the slide mechanism 26 is fed out to move the article M to directly above the fixed shelf 16, the suspension belt 28a is extended by rotating the reel (not illustrated), and the gripper 28b gripping the article M is lowered to a height position of the fixed shelf 16 on which the article M is to be placed. Subsequently, the article M is placed on the fixed shelf 16 by opening the gripper 28b.

Next, when placing the article M on a fixed shelf 16, a placement operation is similarly implemented in a reverse order of the carry-out operation. The fixed shelf 16 is moved inward in the lateral direction by the movement mechanism 20 and the movable shelf 18 is moved to directly below the automated guided vehicle 4. Next, the suspension belt 28a of the gripping mechanism 28 gripping the article M is extended without operating the slide mechanism 26 of the automated guided vehicle 4 to lower the gripper 28b gripping the article to a height position of the movable shelf 18. Subsequently, the article M is placed on the movable shelf 18 by opening the gripper 28b. Subsequently, the movable shelf 18 is returned from the position directly below the automated guided vehicle 4 to its original lateral position by the movement mechanism 20.

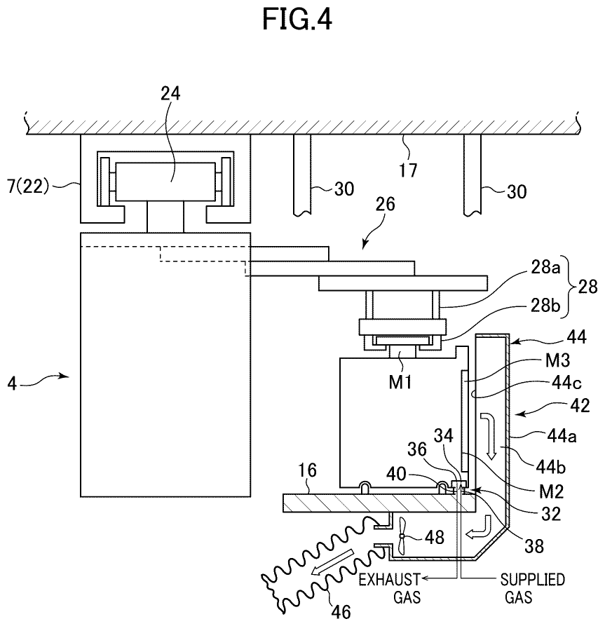

Next, the purge equipment provided on the fixed shelf of the storage system according to the first example embodiment of the present invention will be described with reference to FIG. 4. FIG. 4 is a front view showing a part of the storage sections including the purge equipment provided in the storage system according to the first example embodiment of the present invention.

As shown in FIG. 4, the article M is placed on the fixed shelf 16. As described above, the article M is a container to hold a semiconductor wafer, a reticle, or the like. The fixed shelf 16 is provided with purge equipment 32 to supply a purge gas to the article M.

First, an opening M2 is located on a side of the article M that is a container and the opening M2 is closed by a lid M3. The semiconductor wafer or the like is held inside the container (article M) via the opening M2. In addition, an introduction port 34 for the purge gas and a discharge port 36 for the purge gas are formed on a bottom surface of the container (article M). A check valve (not illustrated) is provided in the introduction port 34 and the discharge port 36 of the purge gas.

The purge equipment 32 is equipment to supply the purge gas into the container (article M). For example, the purge gas is a gas that is inert with respect to the article held in the container such as nitrogen gas. Alternatively, clean dry air that is dried air is also used as the purge gas.

The purge equipment 32 includes a purge nozzle 38 and an exhaust nozzle 40. The purge nozzle 38 and the exhaust nozzle 40 are provided on a top surface of the fixed shelf 16. In addition, the purge nozzle 38 and the exhaust nozzle 40 are arranged so as to be connected to the introduction port 34 of the purge gas and the discharge port 36 of the purge gas of the container (article M), respectively, when the article M is placed on the movable shelf 18. The purge nozzle 38 is connected to a purge gas supply source via piping, and the exhaust nozzle 40 is connected to an exhaust path of the purge gas via piping.

The purge gas purged to the container (article M) may leak from a seal portion of the lid M3 of the container or the like. Depending on a type of the purge gas or a concentration of the purge gas, the leaked purge gas may cause the ambient environment to deteriorate.

Therefore, in the present example embodiment, as shown in FIG. 4, a suction apparatus 42 is provided to prevent the leaked purge gas from staying in a vicinity of the lid M3.

The suction apparatus 42 includes a hood 44, and the hood 44 includes a wall portion 44a, a space portion 44b, and an opening portion 44c. The space portion 44b is located inside the wall portion 44a and the space portion 44b functions as a flow channel of sucked gas. In addition, the opening portion 44c is opened toward the lid M3 of the container (article M) and provides an inflow port of the gas flow channel in the hood 44. In addition, a discharge path 46 is connected to an outflow port of the hood 44 and the gas sucked from the opening portion 44c of the hood 44 is to be discharged by the discharge path 46. Note that a fan 48 is provided in the space portion 44b of the hood and the gas is to be discharged to the outside by driving the fan 48.

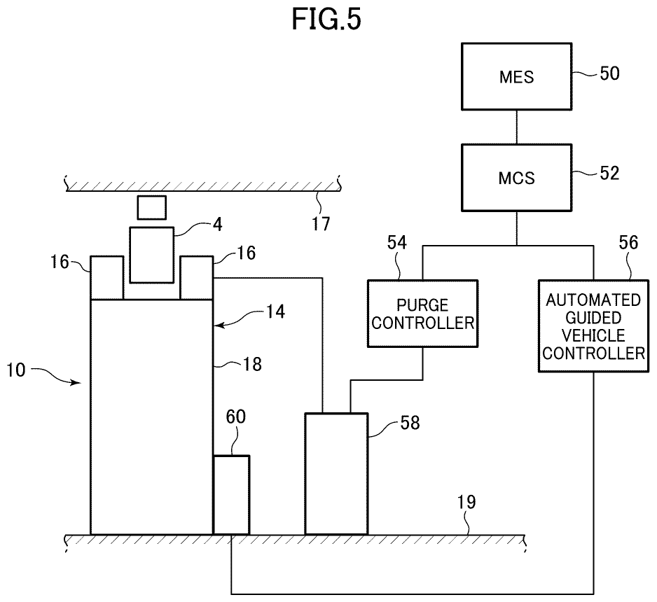

Next, a system configuration of the storage system according to the first example embodiment will be described with reference to FIG. 5. FIG. 5 is a schematic view showing a system configuration of the storage system according to the first example embodiment.

As described above, the storage system 10 includes the automated guided vehicle 4 that travels on the intra-bay tracks 9 and the multistage buffer 14 as the storage equipment 12. The multistage buffer 14 includes the fixed shelf 16 of the uppermost stage and the movable shelves 18 of a plurality of stages positioned below the fixed shelf 16. The fixed shelf 16 is provided with the purge equipment 32 to supply a purge gas to the container (article M).

As shown in FIG. 5, a manufacturing management apparatus (MES) 50, a conveyance management apparatus (MCS) 52, a purge controller 54, a automated guided vehicle controller 56, a fixed shelf control panel 58, and a movable shelf control panel 60 are provided as control devices configured or programmed to operate the storage system 10.

In the present example embodiment, due to these control devices, a purge gas is to be purged to the container (article M) when the article M is placed on the fixed shelf 16 of the multistage buffer 14.

The manufacturing management apparatus (MES) 50 is a controller configured or programmed to perform production management of the factory as a whole, the conveyance management apparatus (MCS) 52 is a controller configured or programmed to manage conveyance of the article M by the automated guided vehicle, the purge controller 54 is a controller configured or programmed to report purge status and errors of the fixed shelf 16 to the conveyance management apparatus (MCS) 52, the automated guided vehicle controller 56 is a controller configured or programmed to provide the movable shelves 18 of the multistage buffer 14 with information on the automated guided vehicle 4, the fixed shelf control panel 58 is a control panel configured or programmed to control purging in the fixed shelf 16, and the movable shelf control panel 60 is a control panel configured or programmed to control movement operations of the movable shelves 18.

Note that the purge controller 54 need not be provided and a purge state and the like need not be reported to the conveyance management apparatus (MCS) 52. In addition, the manufacturing management apparatus (MES) 50 determines which container (article M) in the fixed shelf 16 is to be supplied with the purge gas.

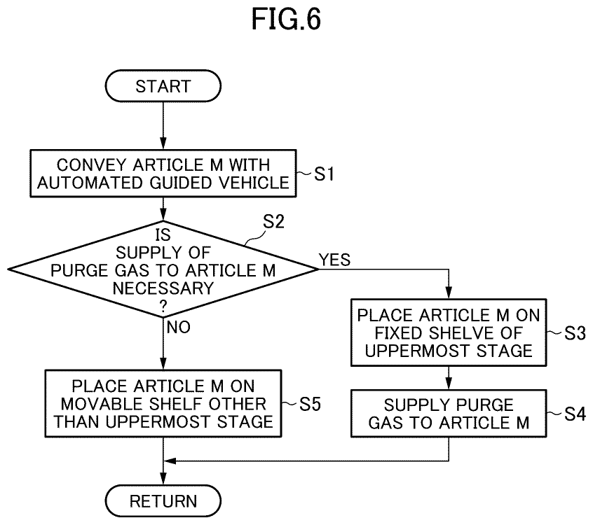

Next, an operation to be executed by the storage system according to the first example embodiment will be described. FIG. 6 is a flow chart showing operations to be executed by the storage system according to the first example embodiment of the present invention. In FIG. 6, S denotes each step.

First, in S1, the article M is conveyed by the automated guided vehicle 4. Next, the operation proceeds to S2 to determine whether or not a supply of the purge gas to the article M is necessary. When a supply of the purge gas is necessary (YES), the operation proceeds to S3.

In S3, the article M is placed on the fixed shelf 16 of the uppermost stage. Next, the operation proceeds to S4 and the purge gas is supplied to the article M.

On the other hand, when it is determined in S2 that supply of the purge gas is unnecessary (NO), the operation proceeds to S5. In S5, the article M is placed on the movable shelves 18 other than the uppermost stage.

Next, operational effects produced by the storage system according to the first example embodiment described above will be described.

First, in the first example embodiment, due to the storage section of the uppermost stage of the storage equipment 12 being the fixed shelf 16 incapable of laterally advancing or retreating, the storage sections other than the uppermost stage being movable shelves 18 capable of advancing or retreating between a position where the storage sections advance to directly below the ceiling track or the automated guided vehicle 4 and a position laterally retracted from directly below the ceiling track or the automated guided vehicle 4 in a top view, and the storage equipment 12 further including purge equipment 32 to supply a purge gas to an article M placed on the fixed shelf 16 of the uppermost stage, since purge gas need only be supplied to the fixed shelf 16 of the uppermost stage by the purge equipment 32 even when storage sections are arranged in a plurality of stages in the up-down direction, an arrangement of piping for purging and the like can be simplified and an extremely practical storage system can be achieved.

Second, in the first example embodiment, since the movable shelves 18 are installed on the floor 19 and the fixed shelf 16 is suspended from the ceiling 17, the movable shelves 18 other than the uppermost stage can be given simple structures by installing the movable shelves 18 on the floor 19.

Third, in the first example embodiment, since the fixed shelf 16 is provided as the fixed storage section and the movable shelves 18 are provided as the movable storage sections, both storage sections can be given simple structures.

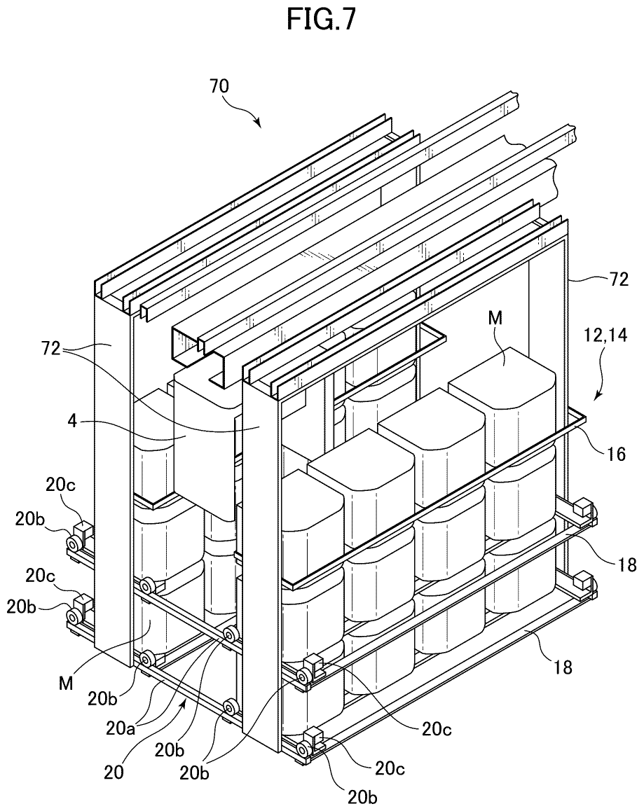

Next, a storage system according to a second example embodiment of the present invention will be described with reference to FIG. 7. FIG. 7 is a perspective view showing the storage system according to the second example embodiment of the present invention.

As shown in FIG. 7, a storage system 70 according to the second example embodiment of the present invention includes the automated guided vehicle 4 that is the ceiling automated guided vehicle described above and the storage equipment 12 to store the article M.

The storage equipment 12 includes multistage buffers 14 arranged on both sides (right side and left side in FIG. 7), respectively, with respect to a traveling direction of the automated guided vehicle 4. The multistage buffer 14 on one side (right side) includes the fixed shelf 16 that is a storage section on an uppermost stage and includes movable shelves 18 of two stages in an up-down direction below the fixed shelf 16. The fixed shelf 16 of the uppermost stage and the movable shelves 18 of the two stages are suspended from the ceiling 17 (refer to FIG. 3) by a suspension rod 72. The fixed shelf 16 is incapable of moving in a lateral direction (width direction) by itself, and the movable shelves 18 are capable of moving the article M in the lateral direction (width direction) to directly below the automated guided vehicle 4. The fixed shelf 16 is provided with the purge equipment 32 to supply a purge gas to the container (article M) in a similar manner to the first example embodiment described above.

The movable shelves 18 are for configured to receive the article M from the automated guided vehicle 4 and store the article M as well as handing the stored article M to the automated guided vehicle 4 and, to that end, the movable shelves 18 can be moved in the lateral direction in a similar manner to the first example embodiment. Therefore, the movable shelf 18 of each stage is provided with the movement mechanism 20 to move the movable shelf 18 in the lateral direction.

The movement mechanism 20 includes the rail 20a provided below each movable shelf 18 and extending in the lateral direction, the roller 20b attached to the movable shelf 18 and travels on the rail 20a, and the drive motor 20c that rotationally drives the roller 20b. Due to the movement mechanism 20, moving the movable shelves 18 to directly below the automated guided vehicle 4 enables the article M to change hands between the movable shelves 18 and the automated guided vehicle 4.

The multistage buffer 14 on the other side (left side) is similar to the right side and includes the fixed shelf 16 that is a storage section on an uppermost stage and includes the movable shelves 18 of two stages below the fixed shelf 16. The fixed shelf 16 of the uppermost stage and the movable shelves 18 of the two stages are suspended from the ceiling 17 (refer to FIG. 3) by the suspension rod 72. The fixed shelf 16 is incapable of moving in a lateral direction (width direction) by itself, and the movable shelves 18 are capable of moving the article M in the lateral direction (width direction) to directly below the automated guided vehicle 4. The movable shelves 18 are also provided with movement mechanisms 20 to move the movable shelves 18 in the lateral direction, and the movement mechanisms 20 also include the rail 20a, the roller 20b, and the drive motor 20c.

Hereinafter, operational effects produced by the storage system according to the second example embodiment described above will be described.

First, in the second example embodiment, operational effects similar to the first and third operational effects produced by the storage system according to the first example embodiment described above are produced.

Second, in the second example embodiment, since all of the fixed shelf 16 and the movable shelves 18 of the storage sections of the plurality of stages are suspended from the ceiling 17, a space between the storage sections of the plurality of stages and the floor 19 can be effectively utilized.

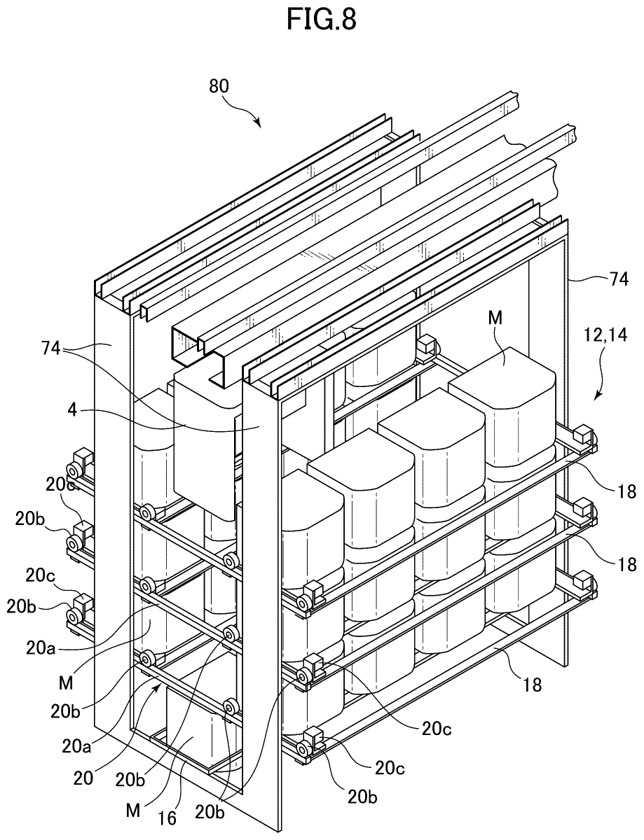

Next, a storage system according to a third example embodiment f the present invention will be described with reference to FIG. 8. FIG. 8 is a perspective view showing the storage system according to the third example embodiment of the present invention.

As shown in FIG. 8, a storage system 80 according to the third example embodiment of the present invention includes the automated guided vehicle 4 that is the ceiling automated guided vehicle described above and the storage equipment 12 to store the article M.

The storage equipment 12 includes multistage buffers 14 arranged on both sides (right side and left side in FIG. 8), respectively, with respect to a traveling direction of the automated guided vehicle 4. The multistage buffer 14 on one side (right side) includes movable shelves 18 of three stages. The movable shelves 18 of the three stages are suspended from the ceiling 17 (refer to FIG. 3) by a suspension rod 74. The movable shelves 18 are capable of moving the article M in the lateral direction (width direction) to directly below the automated guided vehicle 4. The fixed shelf 16 is provided with the purge equipment 32 to supply a purge gas to the container (article M) in a similar manner to the first example embodiment described above.

The movable shelves 18 are configured to receive the article M from the automated guided vehicle 4 and store the article M as well as handing the stored article M to the automated guided vehicle 4 and, to that end, the movable shelves 18 can be moved in the lateral direction in a similar manner to the first example embodiment. Therefore, the movable shelf 18 of each stage is provided with the movement mechanism 20 to move the movable shelf 18 in the lateral direction.

The movement mechanism 20 includes the rail 20a provided below each movable shelf 18 and extending in the lateral direction, the roller 20b attached to the movable shelf 18 and travels on the rail 20a, and the drive motor 20c that rotationally drives the roller 20b. Due to the movement mechanism 20, moving the movable shelves 18 to directly below the automated guided vehicle 4 enables the article M to change hands between the movable shelves 18 and the automated guided vehicle 4.

The multistage buffer 14 on the other side (left side) is similar to the right side and includes the movable shelves 18 of three stages. The movable shelves 18 of the three stages are suspended from the ceiling 17 (refer to FIG. 3) by the suspension rod 74. The movable shelves 18 are capable of moving the article M in the lateral direction (width direction) to directly below the automated guided vehicle 4. The movable shelves 18 are also provided with movement mechanisms 20 to move the movable shelves 18 in the lateral direction, and the movement mechanisms 20 also include the rail 20a, the roller 20b, and the drive motor 20c.

In the third example embodiment, in addition to the movable shelves 18 of three stages described above provided on both sides, respectively, the fixed shelf 16 is provided below the movable shelves 18 and directly below the automated guided vehicle 4. The fixed shelf 16 is suspended by the suspension rod 74 described above. The fixed shelf 16 is incapable of moving in a lateral direction (width direction) by itself.

Hereinafter, operational effects produced by the storage system according to the third example embodiment described above will be described.

First, in the third example embodiment, operational effects similar to the first and third operational effects produced by the storage system according to the first example embodiment described above are produced.

Second, in the third example embodiment, since all of the fixed shelf 16 and the movable shelves 18 of the storage sections of the plurality of stages are suspended from the ceiling 17, a space between the storage sections of the plurality of stages and the floor 19 can be effectively utilized.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-6. (canceled)

7. A storage system, comprising:
a ceiling automated guided vehicle to travel on a ceiling track and convey an article; and
storage equipment that is positioned below and to a side of the ceiling track to receive an article from the ceiling automated guided vehicle and store the article; wherein
the ceiling automated guided vehicle includes a lateral movement apparatus to laterally move a mounted article;
the storage equipment includes storage sections of a plurality of stages arranged in an up-down direction;
the storage section of an uppermost stage of the storage equipment is a fixed storage section incapable of laterally advancing or retreating, the storage sections other than the storage section of the uppermost stage are movable storage sections capable of advancing or retreating between a position where the storage sections advance to directly below the ceiling track and a position laterally retracted from directly below the ceiling track in a top view; and
the storage equipment further includes purge equipment to supply a purge gas to an article placed on the fixed storage section of the uppermost stage.

8. The storage system according to claim 7, wherein the movable storage sections are installed on a floor and the fixed storage section is suspended from the ceiling.

9. The storage system according to claim 7, wherein all of the storage sections of the plurality of stages are suspended from the ceiling.

10. The storage system according to claim 7, wherein the fixed storage section includes a fixed shelf and the movable storage sections include movable shelves.

11. The storage system according to claim 7, further comprising a controller configured or programmed to designate a storage section to store an article and instruct the ceiling automated guided vehicle to transfer the article to the designated storage section; wherein
the controller is configured or programmed to instruct the ceiling automated guided vehicle to transfer the article to the fixed storage section of the uppermost stage when it is determined that the purge gas needs to be supplied to the article, and the controller is configured or programmed to instructs the ceiling automated guided vehicle to transfer the article to a movable storage section other than the uppermost stage when it is determined that the purge gas does not need to be supplied to the article.

12. A storage system, comprising:
a ceiling automated guided vehicle to travel on a ceiling track and convey an article; and
storage equipment that is positioned below and to a side of the ceiling track to receive an article from the ceiling automated guided vehicle and store the article; wherein
the storage equipment includes a plurality of first storage sections that are arranged in an up-down direction and a second storage section that is fixed and arranged below the plurality of storage sections and directly below the ceiling track;
the first storage sections of the storage equipment are movable storage sections that are capable of advancing or retreating between a position where the storage sections advance to directly below the ceiling track and a position laterally retracted from directly below the ceiling track in a top view; and
the storage equipment further includes purge equipment to supply a purge gas to an article placed on the second storage section.
